(19) United States
(12) Patent Application Publication
(10) Pub. No.: US 2025/0193731 A1
(43) Pub. Date: Jun. 12, 2025

(54) CHANNEL INFORMATION PROCESSING METHOD AND APPARATUS, COMMUNICATION DEVICE, AND STORAGE MEDIUM

(71) Applicant: VIVO MOBILE COMMUNICATION CO., LTD., Dongguan (CN)

(72) Inventors: Ang YANG, Dongguan (CN); Tian XIE, Dongguan (CN); Hao WU, Dongguan (CN); Peng SUN, Dongguan (CN)

(21) Appl. No.: 19/053,595

(22) Filed: Feb. 14, 2025

Related U.S. Application Data
(63) Continuation of application No. PCT/CN2023/111731, filed on Aug. 8, 2023.

(30) Foreign Application Priority Data
Aug. 15, 2022 (CN) 202210977681.1

(51) Int. Cl. H04W 28/06

(52) U.S. Cl. CPC H04W 28/06

(57) ABSTRACT

A first device obtains target channel information, where the target channel information includes first channel information and second channel information, and the second channel information is compressed channel information obtained by compressing the first channel information using a first compression method; the first device compresses third channel information by using a second compression method, where the third channel information is at least one of the first channel information and the second channel information, and the second compression method is different from the first compression method; and the first device sends fourth channel information to a second device based on a compression result of compressing the third channel information, where the fourth channel information includes any one of the following: the first channel information and compressed second channel information; compressed first channel information and the second channel information; and compressed first channel information and compressed second channel information.

### CROSS-REFERENCE TO RELATED APPLICATIONS

This application is a bypass continuation application of International Application No. PCT/CN2023/111731, filed on Aug. 8, 2023, which claims the benefit of and priority to Chinese Patent Application No. 202210977681.1, filed on Aug. 15, 2022, both of which being incorporated by reference in their entireties herein.

### TECHNICAL FIELD

This application pertains to the field of communication technologies and, more specifically, relates to a channel information processing method and apparatus, a communication device, and a storage medium.

### BACKGROUND

To ensure joint operation between different network nodes, one network node (referred to as node A herein) may input obtained channel information into an encoder of the node A to obtain output compressed channel information, and send the channel information and the compressed channel information to another network node (referred to as a node B herein), so that the node B corrects an encoder of the node B based on the channel information and the compressed channel information. In this way, the encoder of the node A can match the encoder of the node B to implement joint operation between different network nodes.

### BRIEF SUMMARY

Embodiments of this application provide a channel information processing method and apparatus, a communication device, and a storage medium.

According to a first aspect, a channel information processing method is provided. The method includes: A first device obtains target channel information, where the target channel information includes first channel information and second channel information, and the second channel information is compressed channel information obtained by compressing the first channel information using a first compression method; the first device compresses third channel information by using a second compression method, where the third channel information is at least one of the first channel information and the second channel information, and the second compression method is different from the first compression method; and the first device sends fourth channel information to a second device based on a compression result of compressing the third channel information, where the fourth channel information includes any one of the following: the first channel information and compressed second channel information; compressed first channel information and the second channel information; and compressed first channel information and compressed second channel information.

According to a second aspect, a channel information processing apparatus is provided. The apparatus includes an obtaining module, a compression module, and a sending module. The obtaining module is configured to obtain target channel information, where the target channel information includes first channel information and second channel information, and the second channel information is compressed channel information obtained by compressing the first channel information using a first compression method. The compression module is configured to compress third channel information by using a second compression method, where the third channel information is at least one of the first channel information and the second channel information, and the second compression method is different from the first compression method. The sending module is configured to send fourth channel information to a second device based on a compression result of compressing the third channel information, where the fourth channel information includes any one of the following: the first channel information and compressed second channel information; compressed first channel information and the second channel information; and compressed first channel information and compressed second channel information.

According to a third aspect, a channel information processing method is provided. The method includes: A second device receives fourth channel information sent by a first device, where the fourth channel information includes any one of the following: first channel information and compressed second channel information; compressed first channel information and second channel information; and compressed first channel information and compressed second channel information; and the second device decompresses the fourth channel information by using a target decompression method, where the second channel information is compressed channel information obtained by compressing the first channel information using a first compression method.

According to a fourth aspect, a channel information processing apparatus is provided. The apparatus includes a receiving module and a decompression module. The receiving module is configured to receive fourth channel information sent by a first device, where the fourth channel information includes any one of the following: first channel information and compressed second channel information; compressed first channel information and second channel information; and compressed first channel information and compressed second channel information. The decompression module is configured to decompress the fourth channel information by using a target decompression method, where the second channel information is compressed channel information obtained by compressing the first channel information using a first compression method.

According to a fifth aspect, a communication device is provided. The communication device includes a processor and a memory, and the memory stores a program or an instruction that can be run on the processor. When the program or the instruction is executed by the processor, the steps of the method according to the first aspect are implemented, or the steps of the method according to the third aspect are implemented.

According to a sixth aspect, a communication device is provided, including a processor and a communication interface. The communication interface is configured to obtain target channel information, where the target channel information includes first channel information and second channel information, and the second channel information is compressed channel information obtained by compressing the first channel information using a first compression method. The processor is configured to compress third channel information by using a second compression method, where the third channel information is at least one of the first channel information and the second channel information, and the second compression method is different from the first compression method. The communication interface is further configured to send fourth channel information to a second device based on a compression result of compressing the third channel information, where the fourth channel information includes any one of the following: the first channel information and compressed second channel information; compressed first channel information and the second channel information; and compressed first channel information and compressed second channel information.

Alternatively, the communication interface is configured to receive fourth channel information sent by a first device, where the fourth channel information includes any one of the following: first channel information and compressed second channel information; compressed first channel information and second channel information; and compressed first channel information and compressed second channel information. The processor is configured to decompress the fourth channel information by using a target decompression method, where the second channel information is compressed channel information obtained by compressing the first channel information using a first compression method.

According to a seventh aspect, a communication system is provided, including the first device according to the first aspect and the second device according to the third aspect. The first device may be configured to perform the steps of the channel information processing method according to the first aspect, and the second device may be configured to perform the steps of the channel information processing method according to the third aspect.

According to an eighth aspect, a readable storage medium is provided. The readable storage medium stores a program or an instruction, and when the program or the instruction is executed by a processor, the steps of the method according to the first aspect are implemented, or the steps of the method according to the third aspect are implemented.

According to a ninth aspect, a chip is provided. The chip includes a processor and a communication interface, the communication interface is coupled to the processor, and the processor is configured to run a program or an instruction to implement the method according to the first aspect or the method according to the third aspect.

According to a tenth aspect, a computer program product/program product is provided. The computer program product/program product is stored in a storage medium, and the computer program/program product is executed by at least one processor to implement the steps of the channel information processing method according to the first aspect or the steps of the channel information processing method according to the third aspect.

### BRIEF DESCRIPTION OF DRAWINGS

FIG. 1 is a block diagram of a wireless communication system to which embodiments of this application are applicable;

FIG. 2 is a schematic diagram of a neural network;

FIG. 3 is a schematic diagram of a neuron in a neural network;

FIG. 4 is a first flowchart of a channel information processing method according to an embodiment of this application;

FIG. 5 is a second flowchart of a channel information processing method according to an embodiment of this application;

FIG. 6 is a first schematic diagram of a structure of a channel information processing apparatus according to an embodiment of this application;

FIG. 7 is a second schematic diagram of a structure of a channel information processing apparatus according to an embodiment of this application;

FIG. 8 is a schematic diagram of a communication device according to an embodiment of this application;

FIG. 9 is a schematic diagram of a hardware structure in a case that a communication device is a terminal according to an embodiment of this application; and

FIG. 10 is a schematic diagram of a hardware structure in a case that a communication device is a network side device according to an embodiment of this application.

### DETAILED DESCRIPTION

The following clearly describes the technical solutions in the embodiments of this application with reference to the accompanying drawings in the embodiments of this application. Apparently, the described embodiments are some but not all of the embodiments of this application. All other embodiments obtained by a person of ordinary skill in the art based on the embodiments of this application shall fall within the protection scope of this application.

The terms “first”, “second”, and the like in this specification and claims of this application are used to distinguish between similar objects instead of describing a specific order or sequence. It should be understood that, the terms used in such a way are interchangeable in proper circumstances, so that the embodiments of this application can be implemented in an order other than the order illustrated or described herein. Objects classified by “first” and “second” are usually of a same type, and a quantity of objects is not limited. For example, there may be one or more first objects. In addition, in the description and the claims, “and/or” represents at least one of connected objects, and a character “/” generally represents an “or” relationship between associated objects.

It should be noted that technologies described in the embodiments of this application are not limited to a Long Term Evolution (Long Term Evolution, LTE)/LTE-Advanced (LTE-Advanced, LTE-A) system, and may be further applied to other wireless communication systems such as Code Division Multiple Access (Code Division Multiple Access, CDMA), Time Division Multiple Access (Time Division Multiple Access, TDMA), Frequency Division Multiple Access (Frequency Division Multiple Access, FDMA), Orthogonal Frequency Division Multiple Access (Orthogonal Frequency Division Multiple Access, OFDMA), single-carrier frequency division multiple access (Single-carrier Frequency Division Multiple Access, SC-FDMA), and other systems. The terms “system” and “network” in the embodiments of this application may be used interchangeably. The technologies described can be applied to both the systems and the radio technologies mentioned above as well as to other systems and radio technologies. A new radio (New Radio, NR) system is described in the following description for illustrative purposes, and the NR terminology is used in most of the following description, although these technologies can also be applied to applications other than the NR system application, such as the 6^{th} generation (6^{th} Generation, 6G) communication system.

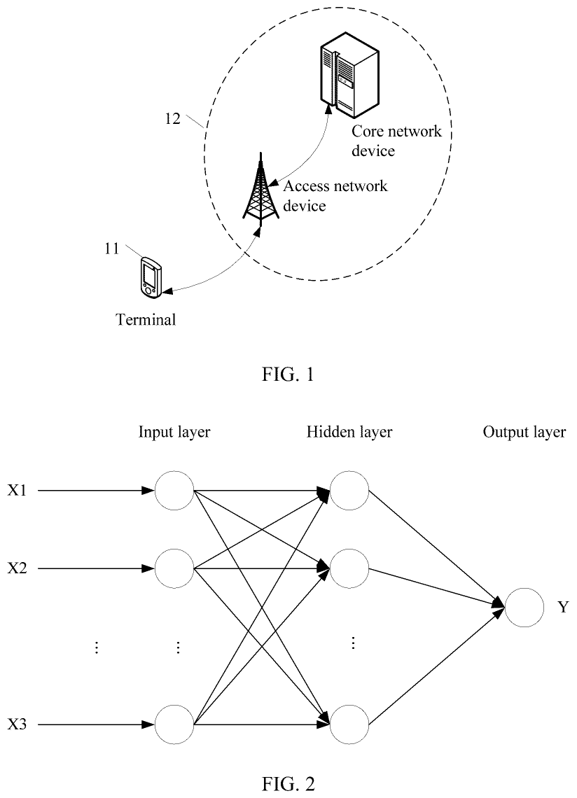

FIG. 1 is a block diagram of a wireless communication system to which the embodiments of this application may be applied. The wireless communication system includes a terminal 11 and a network side device 12. The terminal 11 may be a terminal side device such as a mobile phone, a tablet personal computer (Tablet Personal Computer), a laptop computer (Laptop Computer) that is also referred to as a notebook computer, a personal digital assistant (Personal Digital Assistant, PDA), a palmtop computer, a netbook, an ultra-mobile personal computer (ultra-mobile personal computer, UMPC), a mobile Internet device (Mobile Internet Device, MID), an augmented reality (augmented reality, AR)/virtual reality (virtual reality, VR) device, a robot, a wearable device (Wearable Device), vehicle user equipment (VUE), pedestrian user equipment (PUE), a smart home (a home device with a wireless communication function, such as a refrigerator, a television, a washing machine, or a furniture), a game console, a personal computer (personal computer, PC), a teller machine, or a self-service machine. The wearable device includes a smart watch, a smart band, a smart headset, smart glasses, smart jewelry (a smart bangle, a smart bracelet, a smart ring, a smart necklace, a smart anklet, and a smart chain), a smart wrist strap, a smart dress, and the like. It should be noted that a specific type of the terminal 11 is not limited in the embodiments of this application. The network side device 12 may include an access network device or a core network device. The access network device 12 may also be referred to as a radio access network device, a radio access network (Radio Access Network, RAN), a radio access network function, or a radio access network unit. The access network device 12 may include a base station, a WLAN access point, a Wi-Fi node, or the like. The base station may be referred to as a NodeB, an evolved NodeB (eNB), an access point, a base transceiver station (Base Transceiver Station, BTS), a radio base station, a radio transceiver, a basic service set (Basic Service Set, BSS), an extended service set (Extended Service Set, ESS), a home NodeB, a home evolved NodeB, a transmitting receiving point (Transmitting Receiving Point, TRP), or another appropriate term in the field. As long as a same technical effect is achieved, the base station is not limited to a specified technical term. It should be noted that, in this application, only a base station in an NR system is used as an example, and a specific type of the base station is not limited. The core network device may include but is not limited to at least one of the following: a core network node, a core network function, a mobility management entity (Mobility Management Entity, MME), an access and mobility management function (Access and Mobility Management Function, AMF), a session management function (Session Management Function, SMF), a user plane function (User Plane Function, UPF), a policy control function (Policy Control Function, PCF), a policy and charging rules function unit (Policy and Charging Rules Function, PCRF), an edge application service discovery function (Edge Application Server Discovery Function, EASDF), unified data management (Unified Data Management, UDM), unified data repository (Unified Data Repository, UDR), a home subscriber server (Home Subscriber Server, HSS), centralized network configuration (Centralized network configuration, CNC), a network repository function (Network Repository Function, NRF), a network exposure function (Network Exposure Function, NEF), a local NEF (Local NEF or L-NEF), a binding support function (Binding Support Function, BSF), an application function (Application Function, AF), and the like. It should be noted that, in the embodiments of this application, only a core network device in an NR system is used as an example for description, and a specific type of the core network device is not limited.

A channel information processing method and apparatus, a communication device, and a storage medium provided in the embodiments of this application are described below in detail by using some embodiments and application scenarios thereof with reference to the accompanying drawings.

Currently, artificial intelligence is widely used in various fields, and integrating artificial intelligence into a wireless communication network to significantly improve technical indexes such as a throughput, a delay, and a user capacity is an important task of a future wireless communication network.

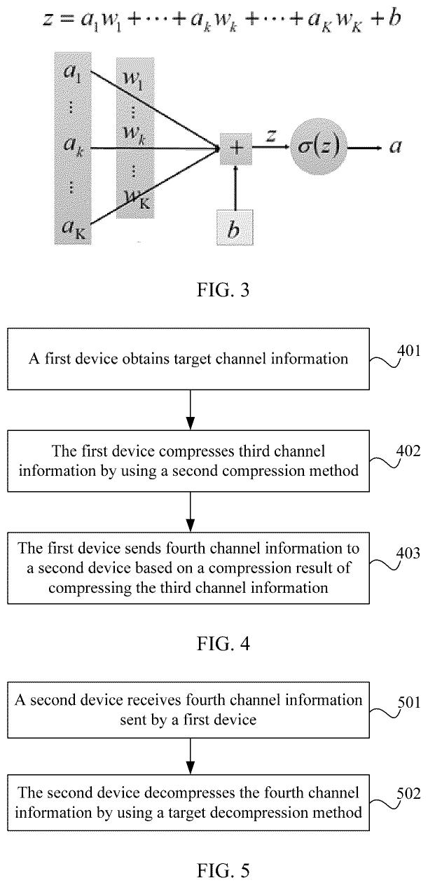

An artificial intelligence module has various implementations, such as a neural network, a decision tree, a support vector machine, and a Bayesian classifier. FIG. 2 is a schematic diagram of a neural network. As shown in FIG. 2, the neural network includes neurons. FIG. 3 is a schematic diagram of a neuron in a neural network. As shown in FIG. 3, a is an input, w is a weight (a multiplicative coefficient), b is an offset (an additive coefficient), and σ(.) is an activation function. Common activation functions may include Sigmoid (that is, an S-type growth curve), tanh (that is, a hyperbolic tangent function), a rectified linear unit (Rectified Linear Unit, ReLU), and the like. Parameters of the neural network may be optimized by using a gradient optimization algorithm. The gradient optimization algorithm is an algorithm for minimizing or maximizing a target function (also referred to as a loss function), and the target function is usually a mathematical combination of model parameters and data. For example, given data x and a corresponding label Y, a neural network model f(.) is constructed. Through the neural network model f(.), x may be input to obtain a predicted output f(x), and a difference (f(x)−Y) between a predicted value and a real value can be calculated. This is a loss function. Appropriate w and b can minimize a value of the loss function, and a smaller loss value makes the neural network model closer to a real case.

Currently, all common optimization algorithms are basically based on an error back propagation (error Back Propagation, BP) algorithm. A basic idea of the BP algorithm is that a learning process consists of two processes: signal forward propagation and error back propagation. During forward propagation, an input sample is transferred from an input layer to an output layer after being processed by each hidden layer. If an actual output of the output layer does not match an expected output, error back propagation is performed. Error back propagation is to transmit an output error layer by layer to the input layer through a hidden layer in some form for back propagation, and allocate the error to all units of each layer, to obtain an error signal of a unit at each layer. This error signal is used as a basis for correcting a weight of each unit. A weight adjustment process of each layer during signal forward propagation and error back propagation is carried out repeatedly. A process of continuously adjusting a weight is a learning and training process of a network. This process continues until errors output by the network are reduced to an acceptable level or until a preset quantity of learning times is reached. Common optimization algorithms include gradient descent (Gradient Descent, GD), stochastic gradient descent (Stochastic Gradient Descent, SGD), mini-batch gradient descent (that is, mini-batch gradient descent), momentum (that is, Momentum), Nesterov (specifically, stochastic gradient descent with momentum), adaptive gradient descent (ADAptive GRADient descent, Adagrad), Adadelta, root mean square prop (root mean square prop, RMSprop), adaptive moment estimation (Adaptive Moment Estimation, Adam), and the like. During error back propagation, in these optimization algorithms, an error/loss is obtained based on the loss function, a gradient is obtained by calculating a derivative/bias derivative of a current neuron and adding an effect such as a learning rate and a previous gradient/derivative/bias derivative, and the gradient is transferred to an upper layer.

In addition, it can be learned from the information theory that accurate channel state information (channel state information, CSI) is crucial for a channel capacity. In particular, for a multi-antenna system, a transmit end may optimize a signal based on CSI, to match a channel state to a larger degree. For example, a channel quality indicator (channel quality indicator, CQI) may be used to select a proper modulation and coding scheme (modulation and coding scheme, MCS) to implement link adaptation, and a precoding matrix indicator (precoding matrix indicator, PMI) may be used to implement eigen beamforming (that is, eigen beamforming) to maximize received signal strength or to suppress interference (for example, inter-cell interference or multi-user interference). Therefore, CSI acquisition has always been a research hotspot since a multi-antenna technology (multi-input multi-output, MIMO) was proposed.

Generally, a base station sends a CSI reference signal on some time-frequency resources of a specific time unit, and a terminal may perform channel estimation based on the CSI reference signal, calculate channel information on the time unit, and feed back a PMI to the base station by using a codebook, so that the base station may obtain channel information through combination based on codebook information fed back by the terminal, and perform data precoding and multi-user scheduling before next CSI reporting. To further reduce CSI feedback overheads, the terminal may change “reporting a PMI on each sub-band” into a “reporting a PMI based on a delay”. Because channels in delay domain are more centralized, PMIs of all sub-bands may be approximately represented by using PMIs of fewer delays, that is, information of the delay domain is compressed before being reported. Similarly, to reduce overheads, the base station may pre-code the CSI reference signal in advance, and send an encoded CSI reference signal to the terminal. What is observed by the terminal is a channel corresponding to the encoded CSI reference signal. Therefore, the terminal only needs to select several ports of relatively high strength from ports indicated by the base station, and report coefficients corresponding to these ports.

Combined with artificial intelligence, there is a type of use case in an air interface design based on artificial intelligence. A model is required to be deployed in modules in a plurality of different network nodes, and a reasoning process is jointly performed by all modules. One of the most typical cases is channel information compression based on artificial intelligence. It is required that an encoder (that is, Encoder) part of the model is deployed on the terminal, and a decoder (that is, Decoder) part of the model is deployed on a base station side, and the encoder and the decoder are jointly used for reasoning. Generally, all modules of the model need to be jointly trained, and this process is usually performed on a network node. Then, the trained modules are distributed to other nodes. However, the foregoing process involves model interaction between network devices from different vendors, and a problem of leakage of intellectual property rights of the model is easily caused. Separate training (that is, separate training) is a method that can avoid the foregoing problem, that is, each node separately trains its own modules, and then ensures, by some means, that the modules can be paired and used. Currently, a most common method for ensuring joint work between modules is that after completing training, a node sends input/output data of the module to another node, and the another node further trains respective modules based on the received data, so that joint work between the modules can be implemented without leaking model details of each node.

However, because the amount of channel information included in input and output data of a module is generally relatively large, overheads for sending input and output data of the module are usually large (far greater than or even hundreds and thousands of times overheads for transmitting the model). Thus, the input and output data needs to be compressed to reduce overheads of data transmission to an acceptable level. However, there is no clear solution to a problem of secondary compression of the input and output data.

To resolve the foregoing problem, in a channel information processing method provided in the embodiments of this application, a first device may obtain target channel information, where the target channel information includes first channel information and second channel information, and the second channel information is compressed channel information obtained by compressing the first channel information using a first compression method. In addition, the first device may compress third channel information by using a second compression method, where the third channel information is at least one of the first channel information and the second channel information, and the second compression method is different from the first compression method. The first device may send fourth channel information to a second device based on a compression result of compressing the third channel information, where the fourth channel information includes any one of the following: the first channel information and compressed second channel information; compressed first channel information and the second channel information; and compressed first channel information and compressed second channel information. In this solution, the first device may first compress the first channel information and/or the second channel information in the target channel information by using the second compression method, and then send the first channel information and the compressed second channel information, or send the compressed first channel information and the second channel information, or send the compressed first channel information and the compressed second channel information to the second device based on the compression result. Therefore, redundancy of the target channel information can be avoided, and therefore, overheads of transmitting the channel information can be reduced.

An embodiment of this application provides a channel information processing method. FIG. 4 is a flowchart of a channel information processing method according to an embodiment of this application. As shown in FIG. 4, the channel information processing method provided in this embodiment of this application may include the following step 401 to step 403.

Step 401: A first device obtains target channel information.

In this embodiment of this application, the target channel information includes first channel information and second channel information, and the second channel information is compressed channel information obtained by compressing the first channel information using a first compression method.

Optionally, in this embodiment of this application, there may be one or more pieces of first channel information, and each piece of second channel information corresponds to one piece of first channel information.

Optionally, in this embodiment of this application, the first channel information may include at least one of the following: information of a reference signal, information of a transmission channel, and information of a control channel.

Optionally, in this embodiment of this application, the reference signal may be a synchronization signal block (Synchronization Signal Block, SSB), a CSI reference signal (that is, CSI-RS), a tracking reference signal (Tracking Reference Signal, TRS), a phase-tracking reference signal (Phase-tracking Reference Signal, PTRS), a sounding reference signal (Sounding Reference Signal, SRS), or the like.

Optionally, in this embodiment of this application, the transmission channel may be a physical downlink shared channel (Physical downlink shared channel, PDSCH), a physical uplink shared channel (Physical Uplink Shared Channel, PUSCH), or the like.

Optionally, in this embodiment of this application, the control channel may be a physical downlink control channel (Physical downlink control channel, PDCCH), a physical uplink control channel (Physical Uplink Control Channel, PUCCH), or the like.

Optionally, in this embodiment of this application, the first compression method may be a compression method of an encoder formed based on a 3rd Generation Partnership Project (3rd Generation Partnership Project, 3GPP) codebook. The 3GPP codebook includes a plurality of types, for example, a type 1 (that is, Type I) codebook and a type 2 (that is, Type II) codebook.

Optionally, in this embodiment of this application, the first compression method may be used to compress channel information into a PMI. Optionally, in this embodiment of this application, the first compression method may include a layer-sharing compression (that is, layer common) method, a layer/rank separate special compression (that is, Layer/rank specific) method, or the like. In the layer-sharing compression method, data is shared and compressed by all layers, that is, channel information of the layers is compressed in parallel and separately (for example, a compression method for each layer in two layers is the same as a compression method for each layer in four layers) regardless of a quantity of layers or a rank, and in addition, information such as a rank does not need to be exchanged. In the layer/rank separate special compression method, different quantities of layers or different ranks use different compression methods (for example, a two-layer compression method is different from a four-layer compression method), and information such as a rank or a layer index needs to be exchanged, or compressed channel information is mapped in a specific sequence (for example, channel information obtained by compressing the layers is mapped in descending order of layer strength).

Step 402: The first device compresses third channel information by using a second compression method.

In this embodiment of this application, the third channel information is at least one of the first channel information and the second channel information, and the second compression method is different from the first compression method.

Optionally, in this embodiment of this application, the second compression method may include at least one of the following: an encoder compression method, a channel information filtering method, a quantization method, a principal component analysis method, and a text compression algorithm.

In this embodiment of this application, because the second compression method may include at least one of the encoder compression method, the channel information filtering method, the quantization method, the principal component analysis method, and the text compression algorithm, the first device may compress the third channel information by using different compression methods, so that flexibility of compressing channel information can be improved.

Optionally, in this embodiment of this application, the foregoing quantization method may include at least one of the following: a uniform quantization method, a non-uniform quantization method, a weight sharing quantization method, a grouping quantization method, a parameter encoding method, a transform domain quantization method, and a product quantization method.

Optionally, in this embodiment of this application, in the weight sharing quantization method or the grouping quantization method, floating points may be classified into a plurality of sets, and elements in each set share one value.

Optionally, in this embodiment of this application, in the parameter encoding method, the floating point may be encoded (including lossy coding or lossless coding), for example, Hoffman coding is performed on the floating point.

Optionally, in this embodiment of this application, in the transform domain quantization method, a floating point may be first transformed into another domain (for example, a frequency domain, an S-domain, or a Z-domain), and then a quantization operation is performed, and then the floating point is reversely transformed back.

Optionally, in this embodiment of this application, in the product quantization method, floating points may be classified into a plurality of sub-spaces, and a quantization operation may be performed in each sub-space.

In this embodiment of this application, because the foregoing quantization method may include at least one of the uniform quantization method, the non-uniform quantization method, the weight sharing quantization method, the grouping quantization method, the parameter encoding method, the transform domain quantization method, and the product quantization method, compression methods used when the first device compresses the third channel information may be enriched, so that flexibility of compressing channel information can be further improved.

Optionally, in this embodiment of this application, the third channel information is the first channel information and the second channel information. Therefore, a compression method used by the first device to compress the first channel information is the same as or different from a compression method used by the first device to compress the second channel information.

In this embodiment of this application, in a case that the compression method used by the first device to compress the first channel information is different from the compression method used by the first device to compress the second channel information, the second compression method includes at least two of the encoder compression method, the channel information screening method, the quantization method, the principal component analysis method, and the text compression algorithm.

In this embodiment of this application, because the compression method used by the first device to compress the first channel information is the same as or different from the compression method used by the first device to compress the second channel information, flexibility of compressing channel information can be further improved.

Optionally, in this embodiment of this application, the foregoing step 402 may be specifically implemented by the following step 402a.

Step 402a: The first device compresses, based on a compression parameter configured by a third device, the third channel information by using the second compression method.

In this embodiment of this application, the third device includes at least one of the following: a core network node, an access network node, and a third-party node.

Optionally, in this embodiment of this application, the core network node may include a network data analytics function (NWDAF, Network Data Analytics Function, NWDAF), a location management function (Location Management Function, LMF), a neural network processing node, or the like.

Optionally, in this embodiment of this application, the access network node may include a base station, a newly defined neural network processing node, or the like.

Optionally, in this embodiment of this application, the third-party node may be an over the top (Over the top, OTT) server, and is generally a node or a device that is not a 3GPP entity.

Optionally, in this embodiment of this application, the first device and the second device each may be a terminal or a network side device, and the first device and the second device may be the same or different.

Optionally, in this embodiment of this application, the compression parameter may include at least one of the following: a compression rate, a codebook parameter, and the like.

In this embodiment of this application, because the first device may compress, based on a compression parameter configured by at least one of the core network node, the access network node, and the third-party node, the third channel information by using the second compression method, accuracy of compressing channel information can be improved.

Specific methods in which the first device compresses the third channel information by using different second compression methods are described in detail below.

Optionally, in this embodiment of this application, the second compression method is the encoder compression method. In this case, the foregoing step 402 may be specifically implemented by the following step 402b and step 402c.

Step 402b: The first device compresses the third channel information through a first encoder by using the encoder compression method, to obtain first compressed channel information, and decompresses the first compressed channel information through a first decoder, to obtain fifth channel information. Optionally, in this embodiment of this application, the first compressed channel information may be a PMI, an encoded bit, compressed information, or the like that is corresponding to the third channel information and that is output by the first encoder after the first device inputs the third channel information into the first encoder.

Optionally, in this embodiment of this application, the first encoder may be an encoder formed based on the 3GPP codebook, and the first encoder may be configured to compress channel information into a PMI.

Optionally, in this embodiment of this application, the first decoder may be a decoder formed based on the 3GPP codebook, and the first decoder may be configured to restore the PMI to any one of the following: channel information, a precoding matrix, and a precoding vector.

In this embodiment of this application, the 3GPP codebook includes a plurality of types, for example, a type 1 (Type I) codebook and a type 2 (Type II) codebook.

Optionally, in this embodiment of this application, the first encoder may be an encoder that is based on a first codebook or may be an encoder that is based on a second codebook.

Optionally, in this embodiment of this application, the first decoder may be a decoder that is based on a first codebook or may be a decoder that is based on a second codebook.

In this embodiment of this application, the second codebook is a codebook obtained by expanding value ranges of some parameters in the first codebook.

For example, a value range of a parameter L (a parameter used to select a quantity of beams) in the first codebook is [1, 2, 3, 4, 6], and in this case, a value range of a parameter L in the second codebook may be less than a quantity of antenna ports for CSI reference signal on a network side; and/or a value of a parameter β (a ratio of non-zero coefficients to all coefficients) in the first codebook is [1/4, 1/2, 3/4], and in this case, a value of a parameter β in the second codebook may further be 1/8, 3/8, 1/16, or the like; and/or a value of a parameter M (used to select a delay quantity) in the first codebook is [1, 2, 4, 8], and in this case, a value of a parameter M in the second codebook may further be 16, 32, or the like; and/or a value of a parameter pᵥ (a parameter of a coefficient used for calculating the parameter M) in the first codebook is [1/8, 1/4, 1/2], and in this case, a value of a parameter pᵥ in the second codebook may further be 1/16, 1/32, 1/64, or the like.

Optionally, in this embodiment of this application, the first codebook may be a 3GPP-based codebook, for example, a Type I codebook or a Type II codebook.

Optionally, in this embodiment of this application, the second codebook may be a codebook obtained by enhancing the 3GPP-based codebook.

In this embodiment of this application, because both the first encoder and the first decoder may be based on the first codebook or based on the second codebook, encoding manners for the first encoder and the first decoder may be enriched, so that flexibility of processing channel information by using the first encoder and the first decoder can be improved.

Step 402c: The first device compresses the fifth channel information by using a second encoder, to obtain second compressed channel information.

Optionally, in this embodiment of this application, the second encoder may be a module that compresses channel information based on the first compression method.

In this embodiment of this application, fourth channel information (that is, compressed target channel information) includes the first compressed channel information and the second compressed channel information.

It should be noted that, because the second compression method is a lossy compression method, compressing the third channel information by using the second compression method causes compression loss of the third channel information. After the third channel information is compressed by using the first encoder, and is decompressed by using the first decoder, and then is compressed by using the second encoder, the obtained second compressed channel information does not have compression loss caused by the first encoder, but channel feature diversity is reduced, that is, the third channel information may be any floating point value, and in this case, the second compressed channel information can only be a limited value in decompressed space. For example, a floating point of the third channel information may be any floating point value between −1 and 1. If the first encoder uses 3-bit uniform quantization, the second compressed channel information can have only eight values.

In this embodiment of this application, because the first device may compress the third channel information by using the encoder to obtain the first compressed channel information, and compress, by using the second encoder, channel information obtained by the first decoder by decompressing the first compressed channel information, to obtain the second compressed channel information, compression loss can be avoided, so that accuracy of processing channel information can be improved.

Optionally, in this embodiment of this application, the first channel information includes at least one piece of channel information, the second channel information includes at least one piece of compressed channel information corresponding to the at least one piece of channel information, and the second compression method is the channel information filtering method. In this case, the first device may specifically compress the third channel information in the following manner 1 and/or manner 2.

### Manner 1

Optionally, in this embodiment of this application, the foregoing step 402 may be specifically implemented by the following step 402d.

Step 402d: The first device clusters the third channel information to obtain N channel information clusters, and selects at least one piece of channel information from each channel information cluster in M channel information clusters.

The N channel information clusters include the M channel information clusters, N is a positive integer, and M is a positive integer less than or equal to N.

In this embodiment of this application, the fourth channel information includes channel information selected from the M channel information clusters.

Optionally, in this embodiment of this application, before the first device clusters the third channel information, a dimension enhancing operation or a dimension reduction operation may be performed first, and then the third channel information is clustered in dimension-enhanced high-dimensional space, or the third channel information is clustered in dimension-reduced low-dimensional space.

Optionally, in this embodiment of this application, the at least one piece of channel information may be channel information at a center point or near a center point of a corresponding channel information cluster.

### Manner 2

Optionally, in this embodiment of this application, the foregoing step 402 may be specifically implemented by the following step 402e.

Step 402e: The first device groups the third channel information into P groups of channel information based on first information, and selects at least one piece of channel information from each group of channel information in Q groups of channel information.

The P groups of channel information include the Q groups of channel information, P is a positive integer, and Q is a positive integer less than or equal to P.

In this embodiment of this application, the fourth channel information includes channel information selected from the Q groups of channel information.

In this embodiment of this application, the first information includes at least one of the following: a signal-to-noise ratio, a line of sight (Line of Sight, LOS), a non-line-of-sight (Non Line Of Sight, NLOS), a frequency domain channel characteristic, a time domain channel characteristic, a space domain channel characteristic, and collection time information of channel information.

For example, the first information includes the signal-to-noise ratio. The first device may group the third channel information into channel information with a signal-to-noise ratio of 10 dB to 11 dB, channel information with a signal-to-noise ratio of 11 dB to 12 dB, and channel information with a signal-to-noise ratio of 12 dB to 13 dB based on the signal-to-noise ratio.

For another example, the first information includes the LOS and the NLOS. The first device may group the third channel information into channel information of the LOS and channel information of the NLOS based on the LOS and the NLOS.

Optionally, in this embodiment of this application, the collection time information of the channel information may include at least one of the following: collection time of the channel information and a collection timestamp of the channel information.

In this embodiment of this application, in a case that the first channel information includes at least one piece of channel information and the second channel information includes at least one piece of compressed channel information corresponding to the at least one piece of channel information, the first device may screen the third channel information in the foregoing manner 1 and/or manner 2 to compress the third channel information, so that flexibility of compressing the third channel information by the first device can be further improved.

Step 403: The first device sends fourth channel information to the second device based on a compression result of compressing the third channel information.

In this embodiment of this application, the fourth channel information includes any one of the following:
(1) the first channel information and compressed second channel information;
(2) compressed first channel information and the second channel information; and
(3) compressed first channel information and compressed second channel information.

It may be understood that if the fourth channel information includes the foregoing (1), the first device compresses the second channel information in the third channel information; if the fourth channel information includes the foregoing (2), the first device compresses the first channel information in the third channel information; and if the fourth channel information includes the foregoing (3), the first device compresses the first channel information and the second channel information in the third channel information.

Optionally, in this embodiment of this application, the first device may send the entire fourth channel information to the second device, to reduce system overheads.

In the channel information processing method provided in this embodiment of this application, the first device may first compress the first channel information and/or the second channel information in the target channel information by using the second compression method, and then send the first channel information and the compressed second channel information, or send the compressed first channel information and the second channel information, or send the compressed first channel information and the compressed second channel information to the second device based on the compression result. Therefore, redundancy of the target channel information can be avoided, and therefore, overheads of transmitting the channel information can be reduced.

An embodiment of this application provides a channel information processing method. FIG. 5 is a flowchart of a channel information processing method according to an embodiment of this application. As shown in FIG. 5, the channel information processing method provided in this embodiment of this application may include the following step 501 and step 502.

Step 501: A second device receives fourth channel information sent by a first device.

In this embodiment of this application, the fourth channel information includes any one of the following:
(1) first channel information and compressed second channel information;
(2) compressed first channel information and second channel information; and
(3) compressed first channel information and compressed second channel information.

The second channel information is compressed channel information obtained by compressing the first channel information using a first compression method.

Step 502: The second device decompresses the fourth channel information by using a target decompression method.

Optionally, in this embodiment of this application, the target decompression method may be a decompression method corresponding to the foregoing second compression method.

Optionally, in this embodiment of this application, the second device decompresses the fourth channel information, to restore the first channel information and the second channel information, and therefore, may perform module training based on the restored channel information, to match an encoding/decoding manner of the first device. In this way, the first device and the second device can work jointly.

Optionally, in this embodiment of this application, the foregoing step 502 may be specifically implemented by the following step 502a.

Step 502a: The second device decompresses, based on a decompression parameter configured by a third device, the fourth channel information by using the target decompression method.

In this embodiment of this application, the third device includes at least one of the following: a core network node, an access network node, and a third-party node.

For other descriptions in this embodiment of this application and an effect that can be implemented by each technical feature, reference may be made to related descriptions in the foregoing embodiments. To avoid repetition, details are not described herein again.

In the channel information processing method provided in this embodiment of this application, in one aspect, because the second device may receive the fourth channel information (that is, compressed channel information) sent by the first device, overheads for receiving channel information can be reduced, and transmission efficiency of channel information can be improved. In another aspect, the second device may decompress the fourth channel information by using the target decompression method, so that the second device can match the encoding manner of the first device, and joint working can be implemented.

The channel information processing method provided in this embodiment of this application is described below as an example.

For example, separate training in which a terminal first trains an encoder and then sends input/output data of an encoder on the terminal side to a base station to help train a decoder is used as an example. The terminal may perform the following steps:

Step 1: The terminal trains an encoder model based on existing channel information.

A method for obtaining channel information required for training includes at least one of the following: The terminal obtains the channel information through estimation based on a downlink reference signal (for example, CSI-RS); the terminal receives channel information sent by another network node; and the terminal generates the channel information by using a simulation model.

A manner in which the terminal trains the encoder includes at least one of the following: first training a complete encoder-decoder model, and then extracting an encoder part for use; and directly training the encoder in a semi-supervised manner.

Step 2: The terminal selects a specific amount of test channel information to obtain paired test channel information (that is, target channel information) by using the encoder model, that is, paired test channel information (that is, first channel information) and test channel compression information (that is, second channel information), where the test channel information is an input of the encoder, and the test channel compression information is an output of the encoder.

A range from which the terminal selects the test channel information is not limited, and may overlap the channel information in step 1. The amount of selected test channel information may be indicated by a network side device, or may be determined by the terminal.

Step 3: The terminal compresses the test channel information in step 2 to obtain paired compressed test channel information and test channel compression information (that is, fourth channel information).

Step 4: The terminal reports the compressed test channel information, the test channel compression information, and information indicating a corresponding decompression method to a base station.

Step 5: The base station receives the compressed test channel information, the test channel compression information, and the information indicating the corresponding decompression method, and restores the channel information based on the corresponding decompression method.

Step 6: The base station trains a decoder based on the restored channel information, and notifies the terminal of a related training result and performs subsequent model management.

For another example, separate training in which the base station first trains the encoder and then sends input/output data required by a terminal side for training the encoder to the terminal to help train the encoder is used as an example. The base station may perform the following steps:

Step a: The base station trains a decoder model based on existing channel information.

A method for obtaining channel information required for training by the base station includes at least one of the following: The base station obtains the channel information through estimation based on an uplink reference signal (for example, an SRS); the base station receives channel information (for example, downlink channel information obtained by a collection terminal through estimation) sent by another network node; and the base station generates the channel information by using a simulation channel model.

A manner in which the base station trains the encoder includes: first training a complete encoder-decoder model, and then extracting a decoder part use.

Step b: The base station selects a specific amount of test channel information and obtains paired test channel information (that is, target channel information), that is, paired test channel information (that is, first channel information) and test channel compression information (that is, second channel information), where the test channel information is an input of an encoder, and the test channel compression information is an output of the encoder.

A range from which the base station selects the test channel information is not limited, and may overlap the channel information in step 1. The amount of selected test channel information may be indicated by a higher layer, or may be determined by the base station.

The selected test channel information needs to adapt to a decoder model of the base station. Generally, the base station mainly uses a decoder module to decompress CSI. However, the base station may obtain the test channel information by using a method such as reserving an encoder module used for training the decoder module.

Step c: The base station compresses the test channel information in step b to obtain paired compressed test channel information and test channel compression information (that is, fourth channel information).

Step d: The base station delivers the compressed test channel information, the test channel compression information, and information indicating a corresponding decompression method to a terminal (or another related network node, such as an OTT server) that requests data or a related function.

Step e: The terminal (or another related network node) receives the compressed test channel information, the test channel compression information, and the information indicating the corresponding decompression method, and restores the channel information based on the corresponding decompression method.

Step f: The terminal (or another related network node) trains the encoder based on the restored channel information, and reports a training result related to the base station and model management information required for performing operations.

The channel information processing method provided in the embodiments of this application may be performed by a channel information processing apparatus. In the embodiments of this application, the channel information processing apparatus performs the channel information processing method is used as an example to describe the channel information processing apparatus provided in the embodiments of this application.

With reference to FIG. 6, an embodiment of this application provides a channel information processing apparatus 60. The channel information processing apparatus 60 may include an obtaining module 61, a compression module 62, and a sending module 63. The obtaining module 61 may be configured to obtain target channel information, where the target channel information includes first channel information and second channel information, and the second channel information is compressed channel information obtained by compressing the first channel information using a first compression method. The compression module 62 may be configured to compress third channel information by using a second compression method, where the third channel information is at least one of the first channel information and the second channel information, and the second compression method is different from the first compression method. The sending module 63 may be configured to send fourth channel information to a second device based on a compression result of compressing the third channel information, where the fourth channel information includes any one of the following: the first channel information and compressed second channel information; compressed first channel information and the second channel information; and compressed first channel information and compressed second channel information.

In a possible implementation, the second compression method may include at least one of the following: an encoder compression method, a channel information filtering method, a quantization method, a principal component analysis method, and a text compression algorithm.

In a possible implementation, the second compression method is the foregoing encoder compression method. The compression module 62 may be specifically configured to: compress the third channel information through a first encoder by using the encoder compression method, to obtain first compressed channel information, decompress the first compressed channel information through a first decoder to obtain fifth channel information, and compress the fifth channel information through a second encoder to obtain second compressed channel information. The fourth channel information includes the first compressed channel information and the second compressed channel information.

In a possible implementation, the first encoder may be an encoder that is based on a first codebook, or may be an encoder that is based on a second codebook; and/or the first decoder may be a decoder that is based on a first codebook, or may be a decoder that is based on a second codebook. The second codebook is a codebook obtained by expanding value ranges of some parameters in the first codebook.

In a possible implementation, the first channel information includes at least one piece of channel information, the second channel information includes at least one piece of compressed channel information corresponding to the at least one piece of channel information, and the second compression method is the foregoing channel information filtering method. The compression module 62 may be specifically configured to: cluster the third channel information to obtain N channel information clusters, and select at least one piece of channel information from each channel information cluster in M channel information clusters, where the N channel information clusters include the M channel information clusters, N is a positive integer, M is a positive integer less than or equal to N, and the fourth channel information includes channel information selected from the M channel information clusters; and/or may be specifically configured to: group the third channel information into P groups of channel information based on first information, and select at least one piece of channel information from each group of channel information in Q groups of channel information, where the P groups of channel information include the Q groups of channel information, P is a positive integer, Q is a positive integer less than or equal to P, the fourth channel information includes channel information selected from the Q groups of channel information, and the first information includes at least one of the following: a signal-to-noise ratio, an LOS, an NLOS, a frequency domain channel characteristic, a time domain channel characteristic, a space domain channel characteristic, and collection time information of channel information.

In a possible implementation, the foregoing quantization method may include at least one of the following: a uniform quantization method, a non-uniform quantization method, a weight sharing quantization method, a grouping quantization method, a parameter encoding method, a transform domain quantization method, and a product quantization method.

In a possible implementation, the third channel information is the first channel information and the second channel information. A compression method used by the first device to compress the first channel information is the same as or different from a compression method used by the first device to compress the second channel information.

In a possible implementation, the compression module 62 may be specifically configured to compress, based on a compression parameter configured by a third device, the third channel information by using the second compression method. The third device includes at least one of the following: a core network node, an access network node, and a third-party node.

In the channel information processing apparatus provided in this embodiment of this application, the channel information processing apparatus may first compress the first channel information and/or the second channel information in the target channel information by using the second compression method, and then send the first channel information and the compressed second channel information, or send the compressed first channel information and the second channel information, or send the compressed first channel information and the compressed second channel information to the second device based on the compression result. Therefore, redundancy of the target channel information can be avoided, and therefore, overheads of transmitting the channel information can be reduced.

The channel information processing apparatus in this embodiment of this application may be an electronic device, for example, an electronic device with an operating system, or may be a component in the electronic device, for example, an integrated circuit or a chip. The electronic device may be a terminal, or another device other than the terminal. For example, the terminal may include but is not limited to the foregoing listed types of the terminal 11, and the another device may be a server, a network attached storage (Network Attached Storage, NAS), or the like. This is not specifically limited in this embodiment of this application.

The channel information processing apparatus provided in this embodiment of this application can implement the processes implemented in the method embodiment in FIG. 4, and a same technical effect is achieved. To avoid repetition, details are not described herein again.

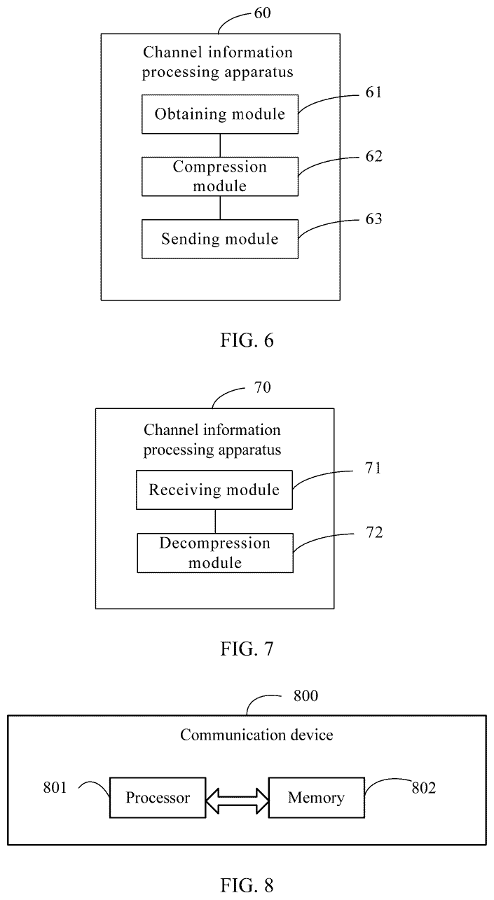

With reference to FIG. 7, an embodiment of this application provides a channel information processing apparatus 70. The channel information processing apparatus 70 may include a receiving module 71 and a decompression module 72. The receiving module 71 may be configured to receive fourth channel information sent by a first device, where the fourth channel information includes any one of the following: first channel information and compressed second channel information; compressed first channel information and second channel information; and compressed first channel information and compressed second channel information. The decompression module 72 may be configured to decompress the fourth channel information by using a target decompression method. The second channel information is compressed channel information obtained by compressing the first channel information using a first compression method.

In a possible implementation, the decompression module 72 may be specifically configured to decompress, based on a decompression parameter configured by a third device, the fourth channel information by using the target decompression method. The third device includes at least one of the following: a core network node, an access network node, and a third-party node.

In the channel information processing apparatus provided in this embodiment of this application, in one aspect, because the channel information processing apparatus may receive the fourth channel information (that is, compressed channel information) sent by the first device, overheads for receiving channel information can be reduced, and transmission efficiency of channel information can be improved. In another aspect, the channel information processing apparatus may decompress the fourth channel information by using the target decompression method, so that the channel information processing apparatus can match an encoding manner of the first device, and joint working can be implemented.

The channel information processing apparatus in this embodiment of this application may be an electronic device, for example, an electronic device with an operating system, or may be a component in the electronic device, for example, an integrated circuit or a chip. The electronic device may be a terminal, or another device other than the terminal. For example, the terminal may include but is not limited to the foregoing listed types of the terminal 11, and the another device may be a server, a network attached storage (Network Attached Storage, NAS), or the like. This is not specifically limited in this embodiment of this application.

The channel information processing apparatus provided in this embodiment of this application can implement the processes implemented in the method embodiment in FIG. 5, and a same technical effect is achieved. To avoid repetition, details are not described herein again.

Optionally, as shown in FIG. 8, an embodiment of this application further provides a communication device 800, including a processor 801 and a memory 802. The memory 802 stores a program or an instruction that can be run on the processor 801. For example, when the communication device 800 is a first device, the program or the instruction is executed by the processor 801 to implement the steps of the foregoing method embodiment on the first device side, and a same technical effect can be achieved. When the communication device 800 is a second device, the program or the instruction is executed by the processor 801 to implement the steps of the foregoing method embodiment on the second device side, and a same technical effect can be achieved. To avoid repetition, details are not described herein again.

An embodiment of this application further provides a communication device, including a processor and a communication interface. The communication interface is configured to obtain target channel information, where the target channel information includes first channel information and second channel information, and the second channel information is compressed channel information obtained by compressing the first channel information using a first compression method. The processor is configured to compress third channel information by using a second compression method, where the third channel information is at least one of the first channel information and the second channel information, and the second compression method is different from the first compression method. The communication interface is further configured to send fourth channel information to a second device based on a compression result of compressing the third channel information, where the fourth channel information includes any one of the following: the first channel information and compressed second channel information; compressed first channel information and the second channel information; and compressed first channel information and compressed second channel information.

Alternatively, the communication interface is configured to receive fourth channel information sent by a first device, where the fourth channel information includes any one of the following: first channel information and compressed second channel information; compressed first channel information and second channel information; and compressed first channel information and compressed second channel information. The processor is configured to decompress the fourth channel information by using a target decompression method, where the second channel information is compressed channel information obtained by compressing the first channel information using a first compression method.

This embodiment of the communication device corresponds to the foregoing embodiment of the channel information processing method. Each implementation process and implementation manner of the foregoing embodiment of the channel information processing method may be applicable to this embodiment of the communication device, and a same technical effect can be achieved. Specifically, the communication device may be a terminal, or may be a network side device.

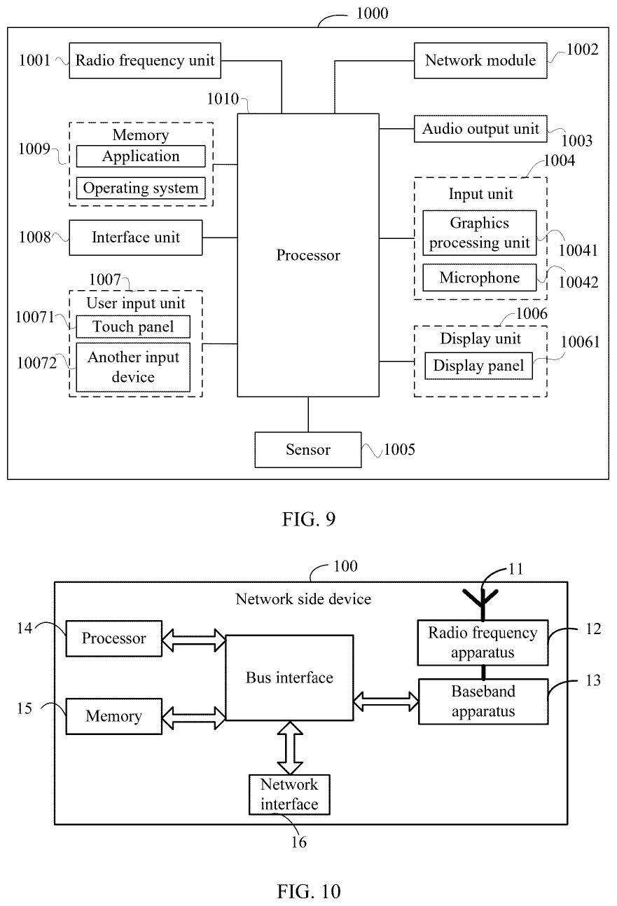

For example, the foregoing communication device is a terminal. FIG. 9 is a schematic diagram of a hardware structure of the terminal.

The terminal 1000 includes but is not limited to at least a part of components such as a radio frequency unit 1001, a network module 1002, an audio output unit 1003, an input unit 1004, a sensor 1005, a display unit 1006, a user input unit 1007, an interface unit 1008, a memory 1009, and a processor 1010.

A person skilled in the art can understand that the terminal 1000 may further include a power supply (such as a battery) that supplies power to each component. The power supply may be logically connected to the processor 1010 by using a power supply management system, to implement functions such as charging and discharging management, and power consumption management by using the power supply management system. The terminal structure shown in FIG. 9 constitutes no limitation on the terminal, and the terminal may include more or fewer components than those shown in the figure, or combine some components, or have different component arrangements. Details are not described herein.

It should be understood that in this embodiment of this application, the input unit 1004 may include a graphics processing unit (Graphics Processing Unit, GPU) 10041 and a microphone 10042. The graphics processing unit 10041 processes image data of a static picture or a video obtained by an image capture apparatus (for example, a camera) in a video capture mode or an image capture mode. The display unit 1006 may include a display panel 10061, and the display panel 10061 may be configured in a form of a liquid crystal display, an organic light-emitting diode, or the like. The user input unit 1007 includes at least one of a touch panel 10071 and another input device 10072. The touch panel 10071 is also referred to as a touchscreen. The touch panel 10071 may include two parts: a touch detection apparatus and a touch controller. The another input device 10072 may include but is not limited to a physical keyboard, a functional button (such as a volume control button or a power on/off button), a trackball, a mouse, and a joystick. Details are not described herein.

In this embodiment of this application, after receiving downlink data from a network side device, the radio frequency unit 1001 may transmit the downlink data to the processor 1010 for processing. In addition, the radio frequency unit 1001 may send uplink data to the network side device. Generally, the radio frequency unit 1001 includes but is not limited to an antenna, an amplifier, a transceiver, a coupler, a low noise amplifier, a duplexer, and the like.

The memory 1009 may be configured to store a software program or an instruction and various data. The memory 1009 may mainly include a first storage area for storing a program or an instruction and a second storage area for storing data. The first storage area may store an operating system, and an application or an instruction required by at least one function (for example, a sound playing function or an image playing function). In addition, the memory 1009 may be a volatile memory or a non-volatile memory, or the memory 1009 may include a volatile memory and a non-volatile memory. The non-volatile memory may be a read-only memory (Read-Only Memory, ROM), a programmable read-only memory (Programmable ROM, PROM), an erasable programmable read-only memory (Erasable PROM, EPROM), an electrically erasable programmable read-only memory (Electrically EPROM, EEPROM), or a flash memory. The volatile memory may be a random access memory (Random Access Memory, RAM), a static random access memory (Static RAM, SRAM), a dynamic random access memory (Dynamic RAM, DRAM), a synchronous dynamic random access memory (Synchronous DRAM, SDRAM), a double data rate synchronous dynamic random access memory (Double Data Rate SDRAM, DDRSDRAM), an enhanced synchronous dynamic random access memory (Enhanced SDRAM, ESDRAM), a synchlink dynamic random access memory (Synch link DRAM, SLDRAM), and a direct rambus random access memory (Direct Rambus RAM, DRRAM). The memory 1009 in this embodiment of this application includes but is not limited to these memories and any memory of another proper type.

The processor 1010 may include one or more processing units. Optionally, an application processor and a modem processor are integrated into the processor 1010. The application processor mainly processes an operating system, a user interface, an application, and the like. The modem processor mainly processes a wireless communication signal, for example, a baseband processor. It may be understood that, alternatively, the modem processor may not be integrated into the processor 1010.

For example, the terminal 1000 is the first device. The radio frequency unit 1001 may be configured to obtain target channel information, where the target channel information includes first channel information and second channel information, and the second channel information is compressed channel information obtained by compressing the first channel information using a first compression method. The processor 1010 may be configured to compress third channel information by using a second compression method, where the third channel information is at least one of the first channel information and the second channel information, and the second compression method is different from the first compression method. The radio frequency unit 1001 may be further configured to send fourth channel information to a second device based on a compression result of compressing the third channel information, where the fourth channel information includes any one of the following: the first channel information and compressed second channel information; compressed first channel information and the second channel information; and compressed first channel information and compressed second channel information.

In a possible implementation, the second compression method may include at least one of the following: an encoder compression method, a channel information filtering method, a quantization method, a principal component analysis method, and a text compression algorithm.

In a possible implementation, the second compression method is the foregoing encoder compression method. The processor 1010 may be specifically configured to: compress the third channel information through a first encoder by using the encoder compression method, to obtain first compressed channel information, decompress the first compressed channel information through a first decoder to obtain fifth channel information, and compress the fifth channel information through a second encoder to obtain second compressed channel information. The fourth channel information includes the first compressed channel information and the second compressed channel information.

In a possible implementation, the first encoder may be an encoder that is based on a first codebook, or may be an encoder that is based on a second codebook; and/or the first decoder may be a decoder that is based on a first codebook, or may be a decoder that is based on a second codebook. The second codebook is a codebook obtained by expanding value ranges of some parameters in the first codebook.

In a possible implementation, the first channel information includes at least one piece of channel information, the second channel information includes at least one piece of compressed channel information corresponding to the at least one piece of channel information, and the second compression method is the foregoing channel information filtering method. The processor 1010 may be specifically configured to: cluster the third channel information to obtain N channel information clusters, and select at least one piece of channel information from each channel information cluster in M channel information clusters, where the N channel information clusters include the M channel information clusters, N is a positive integer, M is a positive integer less than or equal to N, and the fourth channel information includes channel information selected from the M channel information clusters; and/or may be specifically configured to: group the third channel information into P groups of channel information based on first information, and select at least one piece of channel information from each group of channel information in Q groups of channel information, where the P groups of channel information include the Q groups of channel information, P is a positive integer, Q is a positive integer less than or equal to P, the fourth channel information includes channel information selected from the Q groups of channel information, and the first information includes at least one of the following: a signal-to-noise ratio, an LOS, an NLOS, a frequency domain channel characteristic, a time domain channel characteristic, a space domain channel characteristic, and collection time information of channel information.

In a possible implementation, the foregoing quantization method may include at least one of the following: a uniform quantization method, a non-uniform quantization method, a weight sharing quantization method, a grouping quantization method, a parameter encoding method, a transform domain quantization method, and a product quantization method.

In a possible implementation, the third channel information is the first channel information and the second channel information. A compression method used by the first device to compress the first channel information is the same as or different from a compression method used by the first device to compress the second channel information.

In a possible implementation, the processor 1010 may be specifically configured to compress, based on a compression parameter configured by a third device, the third channel information by using the second compression method. The third device includes at least one of the following: a core network node, an access network node, and a third-party node.

In the terminal provided in this embodiment of this application, the terminal may first compress the first channel information and/or the second channel information in the target channel information by using the second compression method, and then send the first channel information and the compressed second channel information, or send the compressed first channel information and the second channel information, or send the compressed first channel information and the compressed second channel information to the second device based on the compression result. Therefore, redundancy of the target channel information can be avoided, and therefore, overheads of transmitting the channel information can be reduced.

The terminal provided in this embodiment of this application can implement the processes implemented by the first device in the foregoing method embodiment, and a same technical effect is achieved. To avoid repetition, details are not described herein again.

For example, the terminal 1000 is the second device. The radio frequency unit 1001 may be configured to receive fourth channel information sent by a first device, where the fourth channel information includes any one of the following: first channel information and compressed second channel information; compressed first channel information and second channel information; and compressed first channel information and compressed second channel information. The processor 1010 may be configured to decompress the fourth channel information by using a target decompression method. The second channel information is compressed channel information obtained by compressing the first channel information using a first compression method.

In a possible implementation, the processor 1010 may be specifically configured to decompress, based on a decompression parameter configured by a third device, the fourth channel information by using the target decompression method. The third device includes at least one of the following: a core network node, an access network node, and a third-party node.

In the terminal provided in this embodiment of this application, in one aspect, because the terminal may receive the fourth channel information (that is, compressed channel information) sent by the first device, overheads for receiving channel information can be reduced, and transmission efficiency of channel information can be improved. In another aspect, the terminal may decompress the fourth channel information by using the target decompression method, so that the terminal can match an encoding manner of the first device, and joint working can be implemented.

The terminal provided in this embodiment of this application can implement the processes implemented by the second device in the foregoing method embodiment, and a same technical effect is achieved. To avoid repetition, details are not described herein again.

For example, the foregoing communication device is a network side device. FIG. 10 is a schematic diagram of a hardware structure of the network side device.

As shown in FIG. 10, the network side device 100 includes an antenna 11, a radio frequency apparatus 12, a baseband apparatus 13, a processor 14, and a memory 15. The antenna 11 is connected to the radio frequency apparatus 12. In an uplink direction, the radio frequency apparatus 12 receives information through the antenna 11, and sends the received information to the baseband apparatus 13 for processing. In a downlink direction, the baseband apparatus 13 processes information that needs to be sent, and sends processed information to the radio frequency apparatus 12. The radio frequency apparatus 12 processes the received information, and sends processed information through the antenna 11.

In the foregoing embodiment, the method performed by the network side device may be implemented in the baseband apparatus 13. The baseband apparatus 13 includes a baseband processor.

For example, the baseband apparatus 13 may include at least one baseband board. A plurality of chips are disposed on the baseband board. One of the chips is, for example, a baseband processor, and is connected to the memory 15 by using a bus interface, to invoke a program in the memory 15 to perform the operations of the network device shown in the foregoing method embodiment.

The network side device may further include a network interface 16, and the interface is, for example, a common public radio interface (common public radio interface, CPRI).

Specifically, the network side device 100 in this embodiment of this application further includes an instruction or a program that is stored in the memory 15 and that can run on the processor 14. The processor 14 invokes the instruction or the program in the memory 15 to perform the method performed by the modules shown in FIG. 6 and FIG. 7, and a same technical effect is achieved. To avoid repetition, details are not described herein again.

For example, the network side device 100 is the first device. The radio frequency apparatus 12 may be configured to obtain target channel information, where the target channel information includes first channel information and second channel information, and the second channel information is compressed channel information obtained by compressing the first channel information using a first compression method. The processor 14 may be configured to compress third channel information by using a second compression method, where the third channel information is at least one of the first channel information and the second channel information, and the second compression method is different from the first compression method. The radio frequency apparatus 12 may be further configured to send fourth channel information to a second device based on a compression result of compressing the third channel information, where the fourth channel information includes any one of the following: the first channel information and compressed second channel information; compressed first channel information and the second channel information; and compressed first channel information and compressed second channel information.

In a possible implementation, the second compression method may include at least one of the following: an encoder compression method, a channel information filtering method, a quantization method, a principal component analysis method, and a text compression algorithm.

In a possible implementation, the second compression method is the foregoing encoder compression method. The processor 14 may be specifically configured to: compress the third channel information through a first encoder by using the encoder compression method, to obtain first compressed channel information, decompress the first compressed channel information through a first decoder to obtain fifth channel information, and compress the fifth channel information through a second encoder to obtain second compressed channel information. The fourth channel information includes the first compressed channel information and the second compressed channel information.

In a possible implementation, the first encoder may be an encoder that is based on a first codebook, or may be an encoder that is based on a second codebook; and/or the first decoder may be a decoder that is based on a first codebook, or may be a decoder that is based on a second codebook. The second codebook is a codebook obtained by expanding value ranges of some parameters in the first codebook.

In a possible implementation, the first channel information includes at least one piece of channel information, the second channel information includes at least one piece of compressed channel information corresponding to the at least one piece of channel information, and the second compression method is the foregoing channel information filtering method. The processor 14 may be specifically configured to: cluster the third channel information to obtain N channel information clusters, and select at least one piece of channel information from each channel information cluster in M channel information clusters, where the N channel information clusters include the M channel information clusters, N is a positive integer, M is a positive integer less than or equal to N, and the fourth channel information includes channel information selected from the M channel information clusters; and/or may be specifically configured to: group the third channel information into P groups of channel information based on first information, and select at least one piece of channel information from each group of channel information in Q groups of channel information, where the P groups of channel information include the Q groups of channel information, P is a positive integer, Q is a positive integer less than or equal to P, the fourth channel information includes channel information selected from the Q groups of channel information, and the first information includes at least one of the following: a signal-to-noise ratio, an LOS, an NLOS, a frequency domain channel characteristic, a time domain channel characteristic, a space domain channel characteristic, and collection time information of channel information.

In a possible implementation, the foregoing quantization method may include at least one of the following: a uniform quantization method, a non-uniform quantization method, a weight sharing quantization method, a grouping quantization method, a parameter encoding method, a transform domain quantization method, and a product quantization method.

In a possible implementation, the third channel information is the first channel information and the second channel information. A compression method used by the first device to compress the first channel information is the same as or different from a compression method used by the first device to compress the second channel information.

In a possible implementation, the processor 14 may be specifically configured to compress, based on a compression parameter configured by a third device, the third channel information by using the second compression method. The third device includes at least one of the following: a core network node, an access network node, and a third-party node.

In the network side device provided in this embodiment of this application, the network side device may first compress the first channel information and/or the second channel information in the target channel information by using the second compression method, and then send the first channel information and the compressed second channel information, or send the compressed first channel information and the second channel information, or send the compressed first channel information and the compressed second channel information to the second device based on the compression result. Therefore, redundancy of the target channel information can be avoided, and therefore, overheads of transmitting the channel information can be reduced.

The network side device provided in this embodiment of this application can implement the processes implemented by the first device in the foregoing method embodiments, and a same technical effect is achieved. To avoid repetition, details are not described herein again.

For example, the network side device 100 is the second device. The radio frequency apparatus 12 may be configured to receive fourth channel information sent by a first device, where the fourth channel information includes any one of the following: first channel information and compressed second channel information; compressed first channel information and second channel information; and compressed first channel information and compressed second channel information. The processor 14 may be configured to decompress the fourth channel information by using a target decompression method. The second channel information is compressed channel information obtained by compressing the first channel information using a first compression method.

In a possible implementation, the processor 14 may be specifically configured to decompress, based on a decompression parameter configured by a third device, the fourth channel information by using the target decompression method. The third device includes at least one of the following: a core network node, an access network node, and a third-party node. In the network side device provided in this embodiment of this application, in one aspect, because the network side device may receive the fourth channel information (that is, compressed channel information) sent by the first device, overheads for receiving channel information can be reduced, and transmission efficiency of channel information can be improved. In another aspect, the network side device may decompress the fourth channel information by using the target decompression method, so that the network side device can match an encoding manner of the first device, and joint working can be implemented.

The network side device provided in this embodiment of this application can implement the processes implemented by the second device in the foregoing method embodiments, and a same technical effect is achieved. To avoid repetition, details are not described herein again.

An embodiment of this application further provides a readable storage medium. A program or an instruction is stored in the readable storage medium. When the program or the instruction is executed by a processor, the processes of the foregoing embodiment of the channel information processing method can be implemented, and a same technical effect can be achieved. To avoid repetition, details are not described herein.

The processor is a processor in the terminal in the foregoing embodiments. The readable storage medium includes a computer-readable storage medium, such as a computer read-only memory ROM, a random access memory RAM, a magnetic disk, or an optical disc.

An embodiment of this application further provides a chip. The chip includes a processor and a communication interface, the communication interface is coupled to the processor, and the processor is configured to run a program or an instruction to implement the processes of the foregoing embodiment of the channel information processing method, and a same technical effect can be achieved. To avoid repetition, details are not described herein again.

It should be understood that the chip mentioned in this embodiment of this application may also be referred to as a system-level chip, a system chip, a chip system, or a system on chip.

An embodiment of this application further provides a computer program/program product, the computer program/program product is stored in a storage medium, and the computer program/program product is executed by at least one processor to implement the processes of the foregoing embodiment of the channel information processing method, and a same technical effect can be achieved. To avoid repetition, details are not described herein again.

An embodiment of this application further provides a communication system, including the first device and the second device that are described in the foregoing embodiments. The first device may be configured to perform the steps of the processes of the method embodiment on the first device side, and the second device may be configured to perform the steps of the processes of the method embodiment on the second device side.

It should be noted that, in this specification, the term “include”, “comprise”, or any other variant thereof is intended to cover a non-exclusive inclusion, so that a process, a method, an article, or an apparatus that includes a list of elements not only includes those elements but also includes other elements which are not expressly listed, or further includes elements inherent to this process, method, article, or apparatus. In absence of more constraints, an element preceded by “includes a . . . ” does not preclude the existence of other identical elements in the process, method, article, or apparatus that includes the element. In addition, it should be noted that the scope of the methods and apparatuses in the embodiments of this application is not limited to performing functions in the order shown or discussed, but may also include performing the functions in a basically simultaneous manner or in opposite order based on the functions involved. For example, the described methods may be performed in a different order from the described order, and various steps may be added, omitted, or combined. In addition, features described with reference to some examples may be combined in other examples.

Based on the descriptions of the foregoing implementations, a person skilled in the art may clearly understand that the method in the foregoing embodiment may be implemented by software in addition to a necessary universal hardware platform or by hardware only. In most circumstances, the former is a preferred implementation. Based on such an understanding, the technical solutions of this application essentially or the part contributing to the prior art may be implemented in a form of a computer software product. The computer software product is stored in a storage medium (for example, a ROM/RAM, a floppy disk, or an optical disc), and includes several instructions for instructing a terminal (which may be a mobile phone, a computer, a server, an air conditioner, a network device, or the like) to perform the methods described in the embodiments of this application.

The embodiments of this application are described above with reference to the accompanying drawings, but this application is not limited to the foregoing specific implementations, and the foregoing specific implementations are only illustrative and not restrictive. Under the enlightenment of this application, a person of ordinary skill in the art can make many forms without departing from the purpose of this application and the protection scope of the claims, all of which fall within the protection of this application.

1. A channel information processing method, wherein the method comprises:
obtaining, by a first device, target channel information, wherein the target channel information comprises first channel information and second channel information, and the second channel information is compressed channel information obtained by compressing the first channel information using a first compression method;
compressing, by the first device, third channel information by using a second compression method, wherein the third channel information is at least one of the first channel information and the second channel information, and the second compression method is different from the first compression method; and
sending, by the first device, fourth channel information to a second device based on a compression result of compressing the third channel information; wherein
the fourth channel information comprises any one of the following:
the first channel information and compressed second channel information;
compressed first channel information and the second channel information; and
compressed first channel information and compressed second channel information.

2. The method according to claim 1, wherein the second compression method comprises at least one of the following: an encoder compression method, a channel information filtering method, a quantization method, a principal component analysis method, and a text compression algorithm.

3. The method according to claim 2, wherein the second compression method is the encoder compression method; and
the compressing, by the first device, third channel information by using a second compression method comprises:
compressing, by the first device, the third channel information through a first encoder by using the encoder compression method, to obtain first compressed channel information, and decompressing the first compressed channel information through a first decoder to obtain fifth channel information; and
compressing, by the first device, the fifth channel information through a second encoder, to obtain second compressed channel information; wherein
the fourth channel information comprises the first compressed channel information and the second compressed channel information.

4. The method according to claim 3, wherein at least one of the following:
the first encoder is an encoder that is based on a first codebook or an encoder that is based on a second codebook;
and
the first decoder is a decoder that is based on a first codebook or a decoder that is based on a second codebook;
wherein the second codebook is a codebook obtained by expanding value ranges of some parameters in the first codebook.

5. The method according to claim 2, wherein the first channel information comprises at least one piece of channel information, the second channel information comprises at least one piece of compressed channel information corresponding to the at least one piece of channel information, and the second compression method is the channel information filtering method; and
the compressing, by the first device, third channel information by using a second compression method comprises:
clustering, by the first device, the third channel information to obtain N channel information clusters, and selecting at least one piece of channel information from each channel information cluster in M channel information clusters, wherein the N channel information clusters comprise the M channel information clusters, Nis a positive integer, and M is a positive integer less than or equal to N; wherein
the fourth channel information comprises channel information selected from the M channel information clusters;
and/or
grouping, by the first device, the third channel information into P groups of channel information based on first information, and selecting at least one piece of channel information from each group of channel information in Q groups of channel information, wherein the P groups of channel information comprise the Q groups of channel information, P is a positive integer, and Q is a positive integer less than or equal to P;
the fourth channel information comprises channel information selected from the Q groups of channel information; and
the first information comprises at least one of the following: a signal-to-noise ratio, a line of sight LOS, a non-line-of-sight NLOS, a frequency domain channel characteristic, a time domain channel characteristic, a space domain channel characteristic, and collection time information of channel information.

6. The method according to claim 2, wherein the quantization method comprises at least one of the following: a uniform quantization method, a non-uniform quantization method, a weight sharing quantization method, a grouping quantization method, a parameter encoding method, a transform domain quantization method, and a product quantization method.

7. The method according to claim 1, wherein the third channel information is the first channel information and the second channel information; and
a compression method used by the first device to compress the first channel information is the same as or different from a compression method used by the first device to compress the second channel information.

8. The method according to claim 1, wherein
the compressing, by the first device, third channel information by using a second compression method comprises:
compressing, by the first device based on a compression parameter configured by a third device, the third channel information by using the second compression method; wherein
the third device comprises at least one of the following: a core network node, an access network node, and a third-party node.

9. A channel information processing method, wherein the method comprises:
receiving, by a second device, fourth channel information sent by a first device, wherein the fourth channel information comprises any one of the following: first channel information and compressed second channel information; compressed first channel information and second channel information; and compressed first channel information and compressed second channel information; and
decompressing, by the second device, the fourth channel information by using a target decompression method; wherein
the second channel information is compressed channel information obtained by compressing the first channel information using a first compression method.

10. The method according to claim 9, wherein the decompressing, by the second device, the fourth channel information by using a target decompression method comprises:
decompressing, by the second device based on a decompression parameter configured by a third device, the fourth channel information by using the target decompression method; wherein the third device comprises at least one of the following: a core network node, an access network node, and a third-party node.

11. A communication device, comprising at least one hardware processor and a memory, wherein the memory stores a program or an instruction that can run on the processor, and when the program or the instruction is executed by the processor, the execution causes the communication device to:
obtain target channel information, wherein the target channel information comprises first channel information and second channel information, and the second channel information is compressed channel information obtained by compressing the first channel information using a first compression method;
compress third channel information by using a second compression method, wherein the third channel information is at least one of the first channel information and the second channel information, and the second compression method is different from the first compression method; and
send fourth channel information to a second device based on a compression result of compressing the third channel information; wherein
the fourth channel information comprises any one of the following:
the first channel information and compressed second channel information;
compressed first channel information and the second channel information; and
compressed first channel information and compressed second channel information.

12. The communication device according to claim 11, wherein the second compression method comprises at least one of the following: an encoder compression method, a channel information filtering method, a quantization method, a principal component analysis method, and a text compression algorithm.

13. The communication device according to claim 12, wherein the second compression method is the encoder compression method; and
the execution further causes the communication device to: compress the third channel information through a first encoder by using the encoder compression method, to obtain first compressed channel information, decompress the first compressed channel information through a first decoder to obtain fifth channel information, and compress the fifth channel information through a second encoder to obtain second compressed channel information; wherein
the fourth channel information comprises the first compressed channel information and the second compressed channel information.

14. The communication device according to claim 13, wherein at least one of:
the first encoder is an encoder that is based on a first codebook or an encoder that is based on a second codebook;
and
the first decoder is a decoder that is based on a first codebook or a decoder that is based on a second codebook;
wherein the second codebook is a codebook obtained by expanding value ranges of some parameters in the first codebook.

15. The communication device according to claim 12, wherein the first channel information comprises at least one piece of channel information, the second channel information comprises at least one piece of compressed channel information corresponding to the at least one piece of channel information, and the second compression method is the channel information filtering method; and
the execution further causes the communication device to: cluster the third channel information to obtain N channel information clusters, and select at least one piece of channel information from each channel information cluster in M channel information clusters, wherein the N channel information clusters comprise the M channel information clusters, Nis a positive integer, and M is a positive integer less than or equal to N; wherein
the fourth channel information comprises channel information selected from the M channel information clusters;
and/or
the execution further causes the communication device to: group the third channel information into P groups of channel information based on first information, and select at least one piece of channel information from each group of channel information in Q groups of channel information, wherein the P groups of channel information comprise the Q groups of channel information, P is a positive integer, and Q is a positive integer less than or equal to P; wherein
the fourth channel information comprises channel information selected from the Q groups of channel information; and
the first information comprises at least one of the following: a signal-to-noise ratio, an LOS, an NLOS, a frequency domain channel characteristic, a time domain channel characteristic, a space domain channel characteristic, and collection time information of channel information.

16. The communication device according to claim 12, wherein the quantization method comprises at least one of the following: a uniform quantization method, a non-uniform quantization method, a weight sharing quantization method, a grouping quantization method, a parameter encoding method, a transform domain quantization method, and a product quantization method.

17. The communication device according to claim 11, wherein the third channel information is the first channel information and the second channel information; and
a compression method used by the first device to compress the first channel information is the same as or different from a compression method used by the first device to compress the second channel information.

18. The communication device according to claim 11, wherein:
the execution further causes the communication device to: compress, based on a compression parameter configured by a third device, the third channel information by using the second compression method; and
the third device comprises at least one of the following: a core network node, an access network node, and a third-party node.

19. A communication device, comprising at least one hardware processor and a memory, wherein the memory stores a program or an instruction that can run on the processor, and when the program or the instruction is executed by the processor, steps of the channel information processing method according to claim 9 are implemented.

20. The communication device according to claim 19, wherein the execution further causes the communication device to:
decompress, based on a decompression parameter configured by a third device, the fourth channel information by using the target decompression method, wherein the third device comprises at least one of the following: a core network node, an access network node, and a third-party node.
